(19) United States
(12) Patent Application Publication
(10) Pub. No.: US 2013/0235528 A1
(43) Pub. Date: Sep. 12, 2013

(54) ASSEMBLED ELECTROMAGNETIC SHIELDING CASE

(71) Applicants: WEN-HSIEN LEE, Yuanshan Township (TW); SHIH-PO LO, New Tapei City (TW); CHING-FENG HSIEH, Taipei City (TW)

(72) Inventors: WEN-HSIEN LEE, Yuanshan Township (TW); SHIH-PO LO, New Tapei City (TW); CHING-FENG HSIEH, Taipei City (TW)

(73) Assignees: ASKEY COMPUTER CORP.; ASKEY TECHNOLOGY (JIANGSU) LTD.

(21) Appl. No.: 13/465,049

(22) Filed: May 7, 2012

(30) Foreign Application Priority Data
Mar. 9, 2012 (TW) 101108099

(51) Int. Cl. H05K 7/20

(52) U.S. Cl. 361/704

(57) ABSTRACT

An assembled electromagnetic shielding case conducive to electromagnetic interference shielding and heat dissipation of an electronic component on a printed circuit board includes a body, a shielding element, and a fixing element. The body has an opening and an engagement portion. The engagement portion connects the body and the printed circuit board. The shielding element has a bottom side and a heat-dissipating side opposing thereto. The shielding element closes the opening for effectuating electromagnetic interference shielding. The shielding element dissipates heat generated from the electronic component by transferring the heat from the bottom side to the heat-dissipating side for dissipating the heat. The fixing element couples the body and the shielding element. Accordingly, with the assembled electromagnetic shielding case, not only is the electronic component insusceptible to electromagnetic interference and easy to change, but it is feasible to provide highly efficient heat dissipation and a miniaturized heat dissipation structure.

### CROSS-REFERENCE TO RELATED APPLICATION

This non-provisional application claims priority under 35 U.S.C. §119(a) on Patent Application No(s).101108099 filed in Taiwan, R.O.C. on Mar. 9, 2012, the entire contents of which are hereby incorporated by reference.

### FIELD OF TECHNOLOGY

The present invention relates to assembled electromagnetic shielding cases, and more particularly, to an assembled electromagnetic shielding case that is easy to install and uninstall.

### BACKGROUND

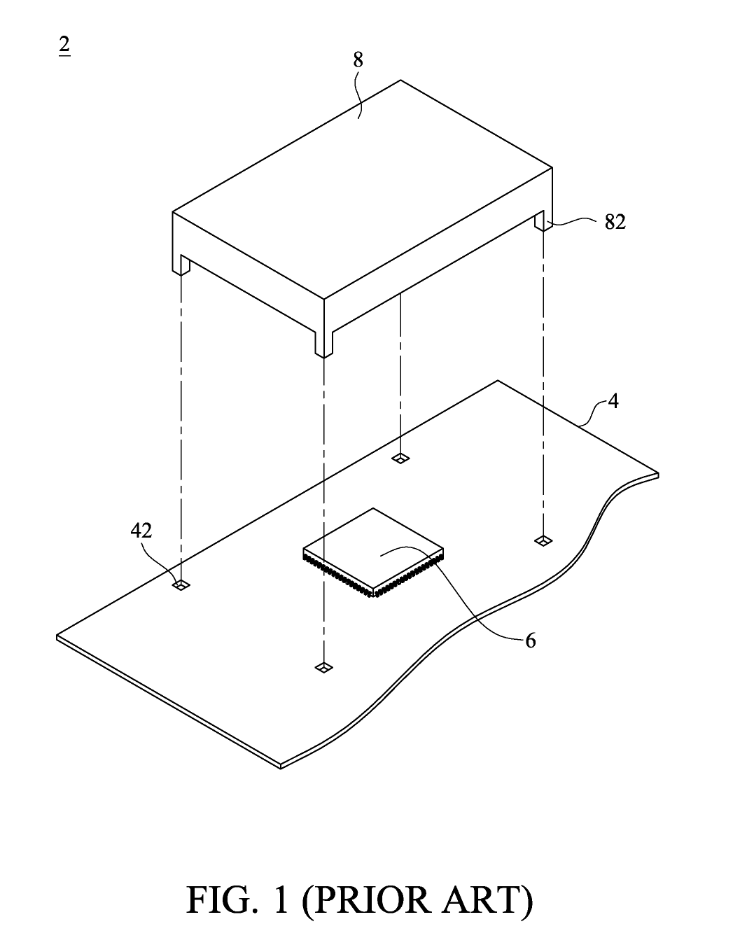

Referring to FIG. 1, according to the prior art, to protect an electronic device 2 against electromagnetic interference (EMI) and the EMI-induced deterioration of the performance of the electronic device 2, a typical protective measures taken involves soldering a shielding housing 8 to a printed circuit board 4 inside the electronic device 2 to cover a related electronic component 6 mounted on the printed circuit board 4 and coupling a plurality of pins 82 of the shielding housing 8 to a plurality of through holes 42 of the printed circuit board 4, respectively, so as to form a shielding case for fending off the electromagnetic interference

However, if the electronic component 6 of the printed circuit board 4 breaks down and needs to be replaced, it will be necessary to unsolder the shielding housing 8 and the printed circuit board 4 in order to carry out the replacement. In general, after being unsoldered, the shielding housing 8 becomes unusable, thereby reducing ease of use and incurring costs.

Furthermore, when covered with the shielding housing 8, the electronic component 6 in operation generates heat that cannot be efficiently dissipated. To enhance heat dissipation, the prior art teaches filling the space defined between the electronic component 6 and the shielding housing 8 with a thermal pad and applying a thermal paste to the shielding housing 8 for enhancing heat dissipation. In practice, the aforesaid attempt to enhance heat dissipation fails. Heat dissipation efficiency decreases, because a bulky heat dissipation structure is formed from the electronic component 6 and plenty of intermediates (such as the thermal pad, the shielding housing 8, the thermal paste, and a heat sink.)

Accordingly, the present invention provides an assembled electromagnetic shielding case whereby an electronic component of an electronic device is not only protected against electromagnetic interference but also replaced conveniently, so as to carry out heat dissipation efficiently and provide a miniaturized heat dissipation structure.

### SUMMARY

It is an objective of the present invention to provide an assembled electromagnetic shielding case for protecting an electronic device against electromagnetic interference and changing an electronic component conveniently.

Another objective of the present invention is to provide an assembled electromagnetic shielding case for effectuating a miniaturized heat dissipation structure and enhancing heat dissipation efficiency.

In order to achieve the above and other objectives, the present invention provides an assembled electromagnetic shielding case conducive to electromagnetic interference shielding and heat dissipation of an electronic component on a printed circuit board. The assembled electromagnetic shielding case comprises a body, a shielding element, and a fixing element. The body has an opening and an engagement portion. The engagement portion connects the body and the printed circuit board. The shielding element closes the opening to provide electromagnetic shielding and has a bottom side and a heat-dissipating side opposing to the bottom side. The shielding element dissipates heat generated from the electronic component by transferring the heat from the bottom side to the heat-dissipating side for dissipating the heat. The fixing element couples the body and the shielding element together.

Compared with the prior art, the present invention provides an assembled electromagnetic shielding case essentially comprising a body and a shielding element coupled thereto, such that an electronic component can be covered with the assembled electromagnetic shielding case to fend off electromagnetic interference, facilitate replacement of the electronic component, effectuate heat dissipation efficiently, and provide a miniaturized heat dissipation structure.

### BRIEF DESCRIPTION

Objectives, features, and advantages of the present invention are hereunder illustrated with specific embodiments in conjunction with the accompanying drawings, in which:

FIG. 1 (PRIOR ART) is a structural schematic view of a conventional shielding housing;

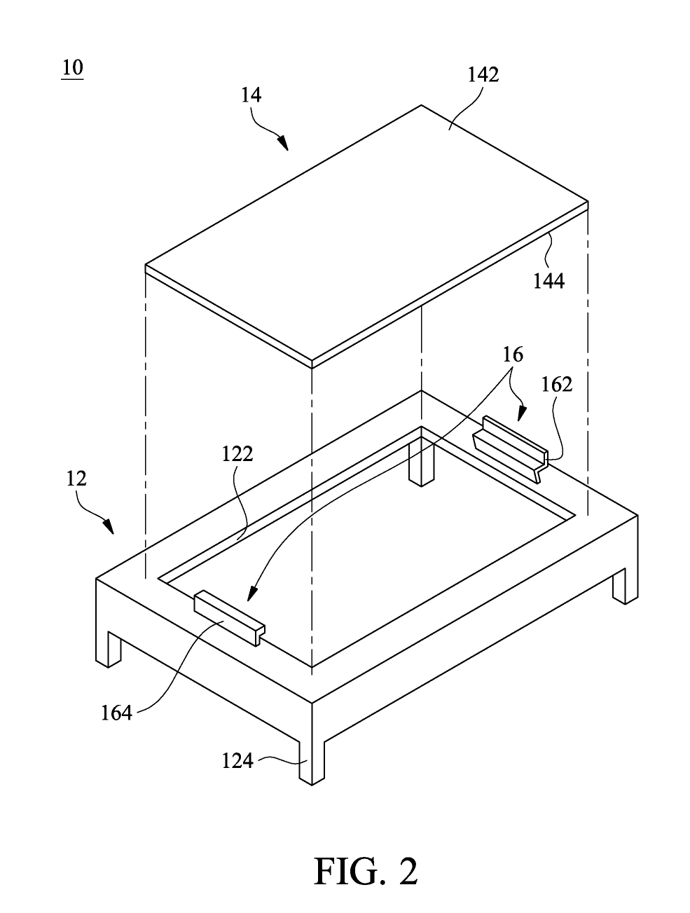

FIG. 2 is a schematic view of an assembled electromagnetic shielding case according to the first embodiment of the present invention;

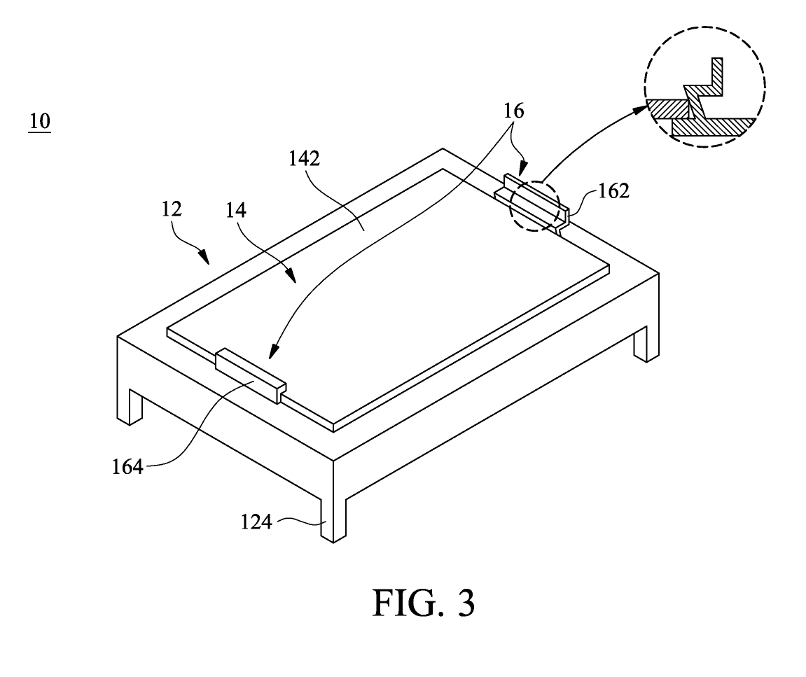

FIG. 3 is another schematic view of the assembled electromagnetic shielding case according to the first embodiment of the present invention;

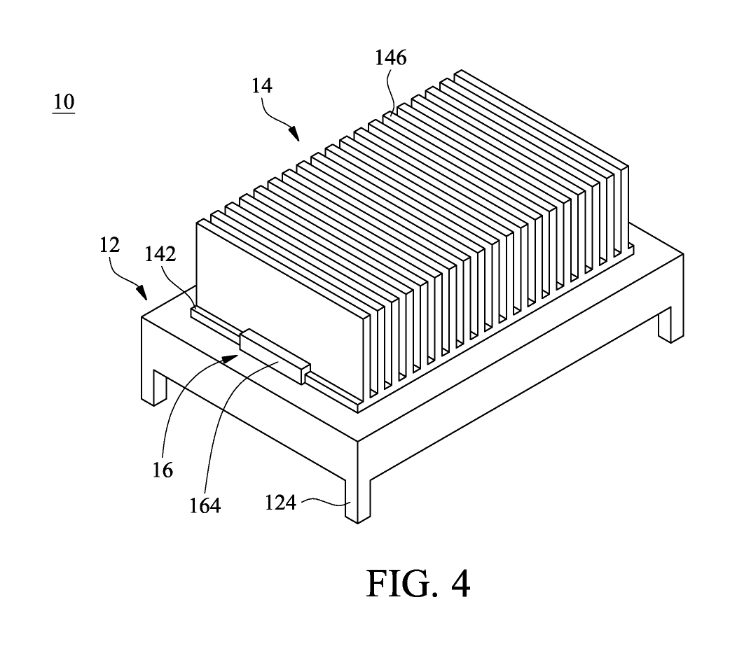

FIG. 4 is yet another schematic view of the assembled electromagnetic shielding case according to the first embodiment of the present invention;

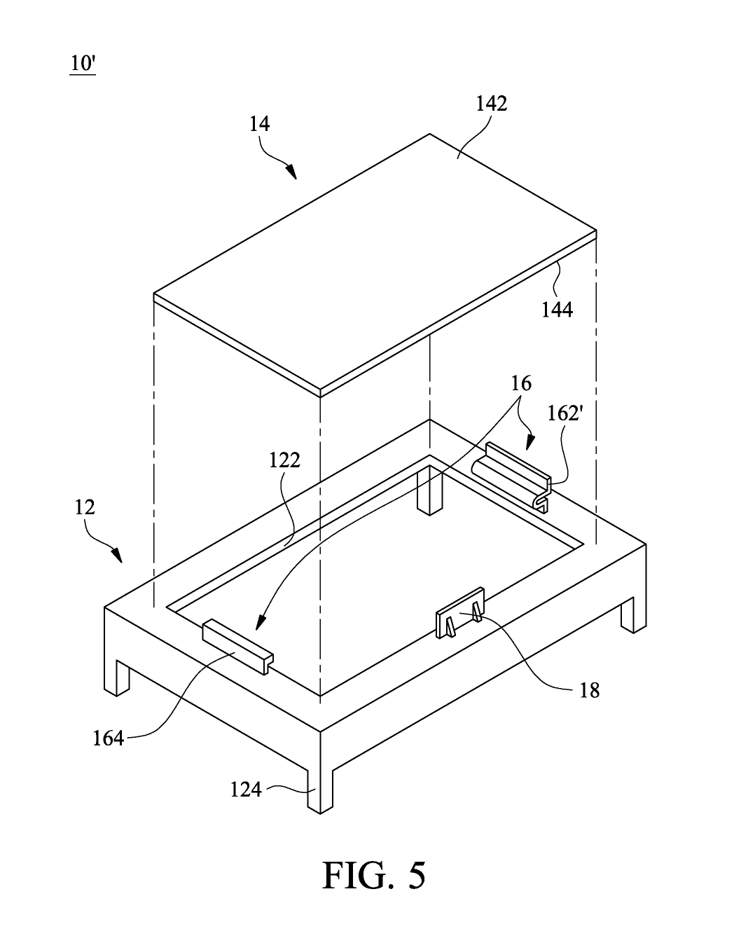

FIG. 5 is a schematic view of an assembled electromagnetic shielding case according to the second embodiment of the present invention;

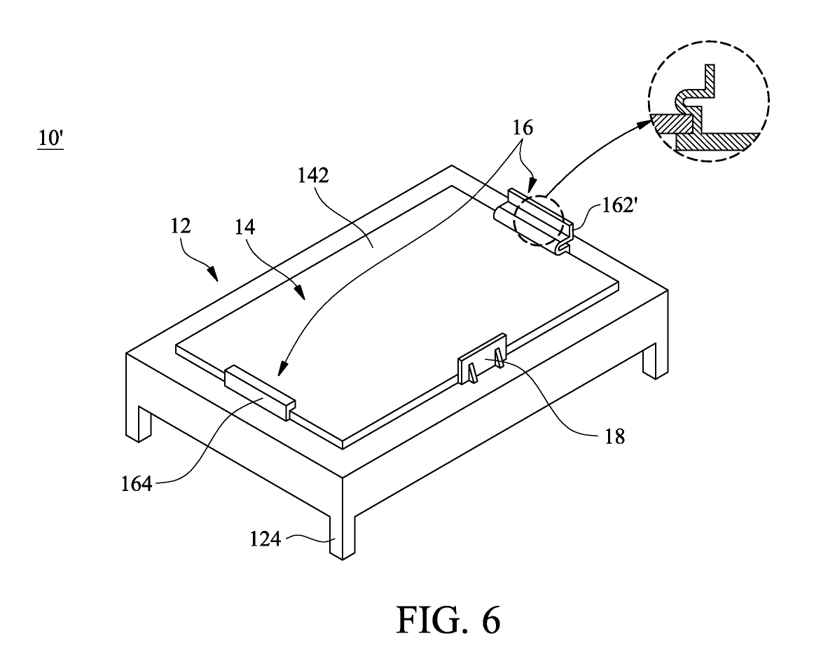

FIG. 6 is another schematic view of the assembled electromagnetic shielding case according to the second embodiment of the present invention;

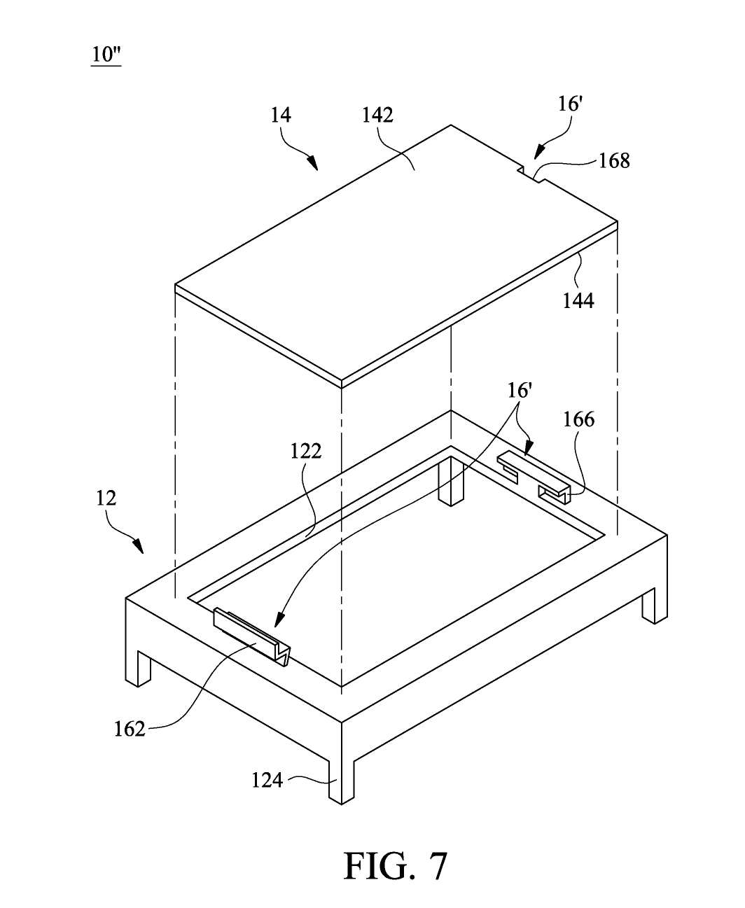

FIG. 7 is a schematic view of an assembled electromagnetic shielding case according to the third embodiment of the present invention;

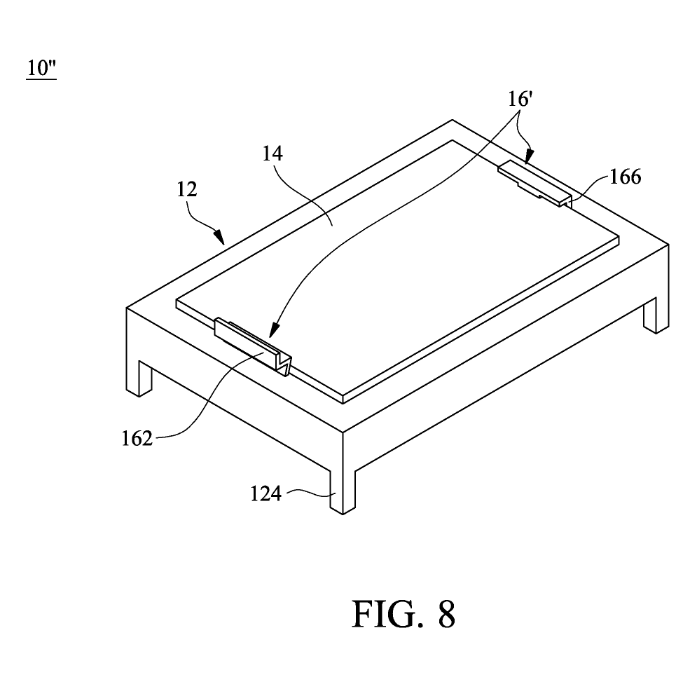

FIG. 8 is another schematic view of the assembled electromagnetic shielding case according to the third embodiment of the present invention; and

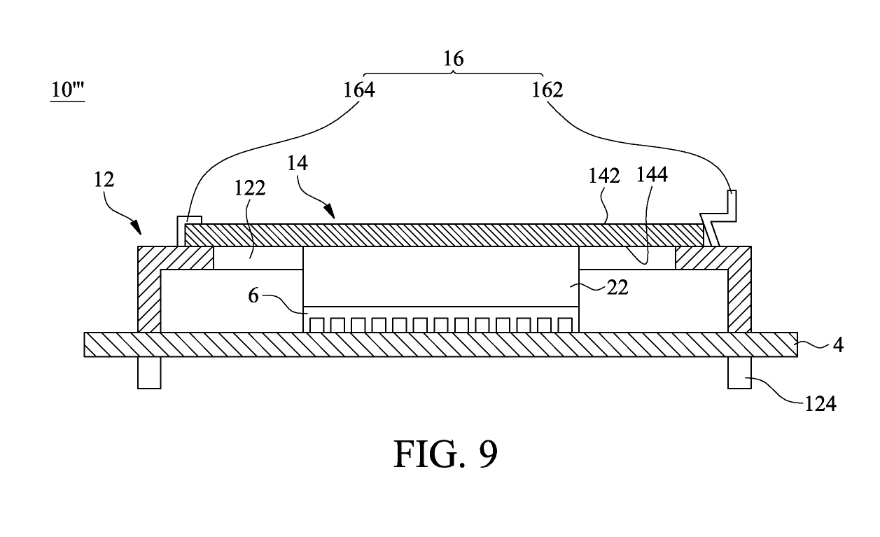

FIG. 9 is a cross-sectional view of an assembled electromagnetic shielding case according to the fourth embodiment of the present invention.

### DETAILED DESCRIPTION

Referring to FIG. 2, there is shown a schematic view of an assembled electromagnetic shielding case 10 according to the first embodiment of the present invention. As shown in FIG. 2, the assembled electromagnetic shielding case 10 enables electromagnetic interference shielding and heat dissipation to occur to an electronic component 6 mounted on a printed circuit board 4 as shown in FIG. 9.

The assembled electromagnetic shielding case 10 comprises a body 12, a shielding element 14, and a fixing element 16. The purpose of the fixing element 16 is to couple the body 12 and the shielding element 14 together.

The body 12 has an opening 122 and an engagement portion 124. The opening 122 is designed to be closed with the shielding element 14. In the first embodiment, the opening 122 is formed on top of the body 12. For example, the opening 122 is formed, by hollowing out the body 12. Alternatively, the body 12 and the opening 122 are integrally formed as a unitary structure. The purpose of the engagement portion 124 is to connect the body 12 and the printed circuit board 4. For example, the engagement portion 124 come in the form of a pin or a means of surface mounted devices (SMD), for fixing the body 12 to the printed circuit board 4 in a removable manner or a fixed manner. The first embodiment is exemplified by the pin-shaped engagement portion 124, wherein the pin-shaped engagement portion 124 is disposed at the edge of the body 12 and protrudes from the body 12. Furthermore, the first embodiment and FIG. 2 are not restrictive of the shape, quantity, and position of the opening 122. In practice, the assembled electromagnetic shielding case 10 of the present invention can have two said openings 122 corresponding in position to two said electronic components 6, respectively. Alternatively, in practice, the opening 122 of the assembled electromagnetic shielding case 10 of the present invention is trapezoidal.

The shielding element 14 has a bottom side 144 and a heat-dissipating side 142 opposing to the bottom side 144. The shielding element 14 is disposed on a surface of the body 12, coupled thereto, and positioned at the opening 122 in a manner that the shielding element 14 closes the opening 122 to provide electromagnetic interference shielding, thereby protecting the electronic component 6 against electromagnetic interference. The shielding element 14 dissipates heat generated from the electronic component 6 by transferring the heat from the bottom side 144 to the heat-dissipating side 142 for dissipating the heat. In an embodiment, the area of the bottom side 144 is larger than or equal to the area of the opening 122. Hence, with the shielding element 14 being capable of closing the opening 122, the shielding element 14 provides electromagnetic interference shielding to the electronic component 6 as soon as the shielding element 14 is coupled to the body 12.

The fixing element 16 serves to couple the body 12 and the shielding element 14 together. For example, the fixing element 16 comprises and a snap-engagement structure, a track structure, and/or a magnetic suction structure. In the first embodiment, the fixing element 16 is exemplified by a snap-engagement structure. Furthermore, in a variant embodiment associated with the first embodiment, the fixing element is disposed at the body 12 or the shielding element 14, or, alternatively, the fixing element is disposed at the body 12 and the shielding element 14. Furthermore, in the first embodiment, the snap-engagement structure, that is, the fixing element 16, comprises a resilient engaging plate 162 and an engaging hook 164. Referring to FIG. 3, the engaging hook 164 is snap-engaged with one edge of the shielding element 14, whereas the resilient engaging plate 162 causes the shielding element 14 to abut against the engaging hook 164, such that the shielding element 14 is fixed to the body 12, thereby preventing the shielding element 14 from moving relative to the body 12.

In case the electronic component 6 mounted on the printed circuit board 4 has to be uninstalled, the user can exert a force upon the resilient engaging plate 162 to cause resilient deformation to the resilient engaging plate 162. As a result, the shielding element 14 separates from the body 12, and then the user can uninstall the electronic component 6 by hand through the opening 122.

Furthermore, any heat generated from the electronic component 6 can be dissipated through the heat-dissipating side 142. Referring to FIG. 4, the assembled electromagnetic shielding case 10 further comprises a heat sink 146 disposed on the heat-dissipating side 142 of the shielding element 14 for enhancing the heat dissipation function of the heat-dissipating side 142. For example, the heat sink 146 is a fin heat sink or a plate heat sink. Hence, the shielding element 14 serves to dissipate heat in the same way as a heat sink does. Furthermore, to position the shielding element 14 at the body 12, the user can position the shielding element 14 above the electronic component 6 mounted on the printed circuit board 4, such that heat generated from the electronic component 6 can be dissipated through the shielding element 14 to thereby lower the temperature of the body 12 and the electronic component 6.

Referring to FIG. 5, there is shown a schematic view of an assembled electromagnetic shielding case 10′ according to the second embodiment of the present invention. As shown in FIG. 5, the assembled electromagnetic shielding case 10′ enables electromagnetic interference shielding and heat dissipation to occur to the electronic component 6 mounted on the printed circuit board 4. In the second embodiment, the assembled electromagnetic shielding case 10′ comprises the body 12, the shielding element 14, the fixing element 16, and a stopping member 18. The stopping member 18 distinguishes the second embodiment from the first embodiment and is disposed at the periphery of the opening 122 for stopping and positioning the shielding element 14 at the opening 122, such that the shielding element 14 can completely hide the opening 122. Precisely speaking, the shielding element 14 is confined to the body 12 by means of the stopping member 18 and thereby prevented from sliding, such that the shielding element 14 can be firmly fixed to the body 12 as shown in FIG. 6.

In the second embodiment, the fixing element 16 comprises a resilient engaging plate 162′ having a flange and the engaging hook 164. Referring to FIG. 6, the engaging hook 164 is snap-engaged with one edge of the shielding element 14, whereas the resilient engaging plate 162′ causes the engaging hook 164 to abut against the shielding element 14. Furthermore, the flange of the resilient engaging plate 162′ is snap-engaged with the other edge of the shielding element 14, such that the shielding element 14 is fixed to the body 12 and prevented from moving relative to the body 12.

Referring to FIG. 7, there is shown a schematic view of an assembled electromagnetic shielding case 10″ according to the third embodiment of the present invention. As shown in FIG. 7, the assembled electromagnetic shielding case 10″ enables electromagnetic interference shielding and heat dissipation to occur to the electronic component 6 mounted on the printed circuit board 4. In the third embodiment, the assembled electromagnetic shielding case 10″ comprises the body 12, the shielding element 14, and a fixing element 16′. The fixing element 16′, which distinguishes the third embodiment from the first and second embodiments, is disposed at both the shielding element 14 and the body 12. The fixing element 16′ couples the shielding element 14 and the body 12 together. In the third embodiment, the fixing element 16′ at the body 12 comprises a T-shaped engaging hook 166 and the resilient engaging plate 162, whereas the fixing element 16′ at the shielding element 14 is implemented in the form of a notch 168. The T-shaped engaging hook 166 corresponds in position to the notch 168 and enables the shielding element 14 to be snap-engaged with the body 12 as shown in FIG. 8.

Referring to FIG. 9, there is shown a cross-sectional view of an assembled electromagnetic shielding case 10″′ according to the fourth embodiment of the present invention. As shown in FIG. 9, the assembled electromagnetic shielding case 10″′ enables electromagnetic interference shielding and heat dissipation to occur to the electronic component 6 mounted on the printed circuit board 4. In the fourth embodiment, the assembled electromagnetic shielding case 10″′ comprises the body 12, the shielding element 14, the fixing element 16, the stopping member 18, and a thermal conductor 22. The thermal conductor 22, which distinguishes the fourth embodiment from the preceding embodiments, is disposed on the bottom side 144 of the shielding element 14 and intended to be positioned between the shielding element 14 and the electronic component 6. For example, the thermal conductor 22 is a thermal pad or a thermal paste. After coming into contact with both the bottom side 144 and the electronic component 6 simultaneously, the thermal conductor 22 transfers heat generated by the electronic component 6 to the shielding element 14, thereby enhancing the heat transfer between the shielding element 14 and the electronic component 6 so as to speed up heat dissipation of the electronic component 6.

Compared with the prior art, the present invention provides an assembled electromagnetic shielding case characterized by a coupling of a body and a shielding element, so as to protect an electronic device against electromagnetic interference, facilitate replacement of an electronic component, achieve highly efficient heat dissipation, and provide a miniaturized heat dissipation structure.

The present invention is disclosed above by preferred embodiments. However, persons skilled in the art should understand that the preferred embodiments are illustrative of the present invention only, but should not be interpreted as restrictive of the scope of the present invention. Hence, all equivalent modifications and replacements made to the aforesaid embodiments should fall within the scope of the present invention. Accordingly, the legal protection for the present invention should be defined by the appended claims.

What is claimed is:

1. An assembled electromagnetic shielding case conducive to electromagnetic interference shielding of an electronic component on a printed circuit board, comprising:
a body having an opening and an engagement portion for connecting the body and the printed circuit board;
a shielding element having a bottom side and a heat-dissipating side opposing thereto, closing the opening to provide electromagnetic interference shielding, and dissipating heat generated from the electronic component by transferring the heat from the bottom side to the heat-dissipating side for dissipating the heat; and
a fixing element coupling the body and the shielding element together.

2. The assembled electromagnetic shielding case of claim 1, wherein the bottom side has an area larger than or equal to the opening.

3. The assembled electromagnetic shielding case of claim 1, wherein the fixing element is disposed on at least one of the body and the shielding element.

4. The assembled electromagnetic shielding case of claim 1, wherein the body further comprises a stopping member for stopping and positioning the shielding element.

5. The assembled electromagnetic shielding case of claim 1, wherein the fixing element comprises at least one of a snap-engagement structure, a track structure, and a magnetic suction structure.

6. The assembled electromagnetic shielding case of claim 1, wherein the fixing element comprises a combination of a resilient engaging plate and an engaging hook or alternatively comprises a combination of a T-shaped engaging hook and a resilient engaging plate.

7. The assembled electromagnetic shielding case of claim 1, further comprising a heat sink disposed on the heat-dissipating side of the shielding element and being one of a fin heat sink and a plate heat sink

8. The assembled electromagnetic shielding case of claim 1, further comprising a thermal conductor disposed on the bottom side of the shielding element to transfer heat generated by the electronic component to the shielding element after the thermal conductor has come into contact with both the bottom side and the electronic component.

9. The assembled electromagnetic shielding case of claim 8, wherein thermal conductor is one of a thermal pad and a thermal paste.

10. The assembled electromagnetic shielding case of claim 1, wherein the engagement portion is a pin disposed at an edge of the body and protruding therefrom.
